(19) United States
(12) Patent Application Publication
(10) Pub. No.: US 2021/0114388 A1
(43) Pub. Date: Apr. 22, 2021

(54) ACTUATOR FAULT INDICATION VIA WIRES ALONG BUSSES

(71) Applicant: Hewlett-Packard Development Company, L.P., Spring, TX (US)

(72) Inventors: Eric Martin, Corvallis, OR (US); James Michael Gardner, Corvallis, OR (US); Daryl E. Anderson, Corvallis, OR (US)

(73) Assignee: Hewlett-Packard Development Company, L.P., Spring, TX (US)

(21) Appl. No.: 16/955,884

(22) PCT Filed: Mar. 5, 2018
(86) PCT No.: PCT/US2018/020883

§ 371 Date: Jun. 19, 2020

(51) Int. Cl. B41J 29/46; B41J 2/045; G01R 17/02; G01R 31/58

(52) U.S. Cl. CPC B41J 29/46; B41J 2/04546; G01R 31/58; B41J 2/0451; G01R 17/02; B41J 2/04586

(57) ABSTRACT

In one example in accordance with the present disclosure, a fluidic die is described. The fluidic die includes an array of fluid actuators. Wires are disposed at various points along at least one of a supply bus and a return bus that are coupled to the actuators in the array. The wires output a voltage level at a corresponding point of the respective bus. At least one comparator compares a voltage of a selected wire against a voltage threshold. At least one fault capture device to output a signal indicating a fault based on the output of the at least one comparator.

### BACKGROUND

A fluidic die is a component of a fluidic system. The fluidic die includes components that manipulate fluid flowing through the system. For example, a fluidic ejection die, which is an example of a fluidic die, includes a number of nozzles that eject fluid onto a surface. The fluidic die also includes non-ejecting actuators such as micro-recirculation pumps that move fluid through the fluidic die. Through these nozzles and pumps, fluid, such as ink and fusing agent among others, is ejected or moved.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a block diagram of a fluidic die for zonal actuator evaluation via wires along busses, according to an example of the principles described herein.

FIG. 2 is a diagram of a fluidic die for zonal actuator evaluation via wires along busses, according to an example of the principles described herein.

FIG. 3 is a flow chart of a method for zonal actuator evaluation via wires along busses, according to an example of the principles described herein.

FIG. 4 is a diagram of a fluidic die for zonal actuator evaluation via wires along busses, according to an example of the principles described herein.

FIG. 5 is a circuit diagram of comparators and fault capture devices, according to an example of the principles described herein.

FIG. 6 is a flow chart of a method for zonal actuator evaluation via wires along busses, according to an example of the principles described herein.

FIG. 7 is a diagram of a fluidic die for zonal actuator evaluation via wires along busses, according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

Fluidic dies, as used herein, may describe a variety of types of integrated devices with which small volumes of fluid may be pumped, mixed, analyzed, ejected, etc. Such fluidic dies may include ejection dies, such as those found in printers, additive manufacturing distributor components, digital titration components, and/or other such devices with which volumes of fluid may be selectively and controllably ejected.

In a specific example, these fluidic systems are found in any number of printing devices such as inkjet printers, multi-function printers (MFPs), and additive manufacturing apparatuses. The fluidic systems in these devices are used for precisely, and rapidly, dispensing small quantities of fluid. For example, in an additive manufacturing apparatus, the fluid ejection system dispenses fusing agent. The fusing agent is deposited on a build material, which fusing agent facilitates the hardening of build material to form a three-dimensional product.

Other fluid systems dispense ink on a two-dimensional print medium such as paper. For example, during inkjet printing, fluid is directed to a fluid ejection die. Depending on the content to be printed, the device in which the fluid ejection system is disposed determines the time and position at which the ink drops are to be released/ejected onto the print medium. In this way, the fluid ejection die releases multiple ink drops over a predefined area to produce a representation of the image content to be printed. Besides paper, other forms of print media may also be used.

Accordingly, as has been described, the systems and methods described herein may be implemented in a two-dimensional printing, i.e., depositing fluid on a substrate, and in three-dimensional printing, i.e., depositing a fusing agent or other functional agent on a material base to form a three-dimensional printed product.

Each fluidic die includes a fluid actuator to eject/move fluid. In a fluidic ejection die, a fluid actuator may be disposed in an ejection chamber, which chamber has an opening. The fluid actuator in this case may be referred to as an ejector that, upon actuation, causes ejection of a fluid drop via the opening.

Fluid actuators may also be pumps. For example, some fluidic dies include microfluidic channels. A microfluidic channel is a channel of sufficiently small size (e.g., of nanometer sized scale, micrometer sized scale, millimeter sized scale, etc.) to facilitate conveyance of small volumes of fluid (e.g., picoliter scale, nanoliter scale, microliter scale, milliliter scale, etc.). Fluidic actuators may be disposed within these channels which, upon activation, may generate fluid displacement in the microfluidic channel.

Examples of fluid actuators include a piezoelectric membrane based actuator, a thermal resistor based actuator, an electrostatic membrane actuator, a mechanical/impact driven membrane actuator, a magneto-strictive drive actuator, or other such elements that may cause displacement of fluid responsive to electrical actuation. A fluidic die may include a plurality of fluid actuators, which may be referred to as an array of fluid actuators.

While such fluidic systems and dies undoubtedly have advanced the field of precise fluid delivery, some conditions impact their effectiveness. For example, the power delivery regime of a fluidic die may not be able to keep up with other technological changes to the fluidic die. For example, as fluidic dies shrink in size to meet consumer demand or as more circuit elements are added between the power source and the array of fluid actuators, power delivery becomes more difficult as there are fewer thin film layers through which power can be delivered and more components that act as a source of parasitic loss. Each of these circumstances may have a deleterious effect on fluidic performance.

For example, the energy a fluid actuator uses to effectuate fluid manipulation is related to the voltage difference across it. Accordingly, a drop in electrical power may affect the fluid actuator's ability to perform an operation such as fluidic ejection or fluidic movement. As a specific numeric example, an actuator array may be optimized to operate when coupled to a 32 V supply signal and a ground signal. However, due to parasitic losses, which may be more prevalent with reduced size components, the supply voltage that is actually seen by an actuator in the array may be 28 V and the power return node at the same actuator may be at 3V instead of 0 V due to parasitic rise. Consequently, instead of 32 V across the fluid actuator, there would be a 25 V differential across the fluid actuator. This reduced voltage may result in an actuation of the fluid actuator that is not full strength and thus affects ejection/movement of the fluid, or may not result in any ejection/movement at all. Such losses may be more prevalent at those positions along the array furthest from a power supply or a return, for example, a middle region of a column array. Additionally, for fluidic systems that include multiple fluidic die, those die located further from the system power supply will experience more parasitic losses.

Accordingly, the present specification is directed to a fluidic die that includes multiple arrays of fluid actuators. Components on the fluidic die monitor power delivery to fluid actuators. If a supply voltage level drops below a threshold value or if a return voltage level rises above a threshold value, a fault signal is sent to global circuitry that informs the printer. The printer could then make any variety of adjustments including adjusting print masks, power settings, or other parameters to bring the power delivery back to a desired level. Specifically, a controller could increase the supply voltage, reduce the number of nozzles that are fired at the same time, slow down the print speed so that the amount of fluid per area remains the same as before, and increase a pulse width of power delivered to the fluid actuators. As such, a device in which the fluidic die is included, can optimize printing based on actual power delivery to the fluidic die and that is specific to that fluidic die.

In this particular example, the circuitry that makes the fault detection includes wires that are disposed at positions along return and/or supply busses likely to experience a fault. For example, power distribution to the array of fluid actuators varies relative to a position along the fluidic die with fluid actuators that are disposed at a center of the array being likely to see a greater parasitic loss than those fluid actuators that are disposed near the supply source. Accordingly, wires are disposed along the supply bus and return bus at these locations and corresponding voltage signals passed to fault detection devices.

In some examples, the fault detection devices are located outside an area that is defined by the array of fluid actuators. That is, the area within a fluidic die where the array of fluid actuators is located is densely populated with circuitry such as the fluidic ejection devices themselves, i.e., nozzles, and components to deliver fluid and electrical power to those fluidic ejection devices. Accordingly, adding fault detection devices in that area further increases the circuit density. Any increase to circuit density makes formation of fluidic die both more complex and costly. It also introduces additional potential sources of mechanical or electrical failure. Accordingly, the fluidic die of the present specification locates these elements outside of an area defined by the fluid actuators. Doing so frees up space in this area and places the fault detection devices in a location where it is more easily placed. Moreover, the configuration of the fault detection device is such that fault detection is not compromised.

Specifically, the present specification describes a fluidic die. The fluidic die includes an array of fluid actuators. The fluidic die also includes a number of wires disposed at various points along at least one of a supply bus and a return bus that are coupled to fluid actuators in the array. The wires return a voltage level at a corresponding point of the respective bus. At least one comparator of the fluidic die compares a voltage of a selected wire against a voltage threshold. The fluidic die also includes at least one fault capture device to output a signal indicating a fault based on the output of the at least one comparator.

The present specification also describes a method. According to the method, a selected supply wire of multiple supply wires is coupled to a comparator. The supply wires 1) are disposed at various points along a supply bus that is coupled to fluid actuators in an array and 2) output a supply voltage level at a corresponding point of the supply bus. A voltage on the selected supply wire is then compared against a supply voltage threshold. A selected return wire of multiple return wires is also coupled to the comparator. The return wires 1) are disposed at various points along a return bus that is coupled to the fluid actuators in the array and 2) are to output a return voltage level at a corresponding point of the return bus. A voltage on the selected return wire is then compared against a return voltage threshold. A fault at a location is determined when either 1) the voltage on the selected supply wire is less than the supply voltage threshold or 2) the voltage on the selected return wire is greater than the return voltage threshold.

The present specification also describes the fluidic die that includes the array of fluid actuators. In this example multiple supply wires are disposed at various points along a supply bus that is coupled to the array and multiple return wires are disposed at various points along a return bus that is coupled to the array. In this example, the fluidic die includes a first multiplexer to couple a selected supply wire to a first comparator, the first comparator to compare a voltage of the selected supply wire against a supply voltage threshold. A first fault capture device outputs a signal indicating a fault based on the output of the first comparator. The fluidic die also includes a second multiplexer to couple a selected return wire to a second comparator, the second comparator to compare a voltage of the selected return wire against a return voltage threshold. A second fault capture device outputs a signal indicating a fault based on the output of the second comparator.

In one example, using such a fluidic die 1) allows for immediate detection of power faults at particular locations within the array of fluid actuators; 2) reports such faults such that remedial action may be taken; 3) allows for a controller to adjust print masks, power distribution, print speed, firing parameters, or other parameters, on the fly to optimize for the actual power delivery limitations of the system; 4) can repurpose existing fluidic die elements; 5) implements supply and return wires having a small width; and 6) removes detection circuitry from within an actuator array.

As used in the present specification and in the appended claims, the term “actuator” refers to an ejecting actuator and/or a non-ejecting actuator. For example, an ejecting actuator operates to eject fluid from the fluid ejection die. A recirculation pump, which is an example of a non-ejecting actuator, moves fluid through the fluid slots, channels, and pathways within the fluidic die.

Accordingly, as used in the present specification and in the appended claims, the term “nozzle” refers to an individual component of a fluid ejection die that dispenses fluid onto a surface. The nozzle includes at least an ejection chamber, an ejector actuator, and an opening.

Further, as used in the present specification and in the appended claims, the term “fluidic die” refers to a component of a fluid ejection system that includes a number of fluid actuators. A fluidic die includes fluidic ejection dies and non-ejecting fluidic dies.

Further, as used in the present specification and in the appended claims, the term “array” refers to a grouping of fluid actuators. A fluidic die may include multiple “arrays.” For example, a fluidic die may include multiple columns, each column forming an array.

Further, as used in the present specification and in the appended claims, the term “fault capture device,” refers to an electrical component that can store a signal, such as a logic value. Examples of capture devices include flip-flops such as a set-reset flop, a D flip-flop, and others.

Further, as used in the present specification and in the appended claims, the term “fault-indicating output” refers to an output of a comparator that indicates a particular fault. For example, a comparator may generate an output indicating that the supply voltage at a location within the array is less than a threshold amount, which is indicative of a fault. The comparator may then generate an output indicating this fault.

Further, as used in the present specification and in the appended claims, the term “bus” refers to a supply bus or return bus that provides power to the array of fluid actuators. The supply busses and return busses may be conductive thin films formed of, for example aluminum or gold.

Further, as used in the present specification and in the appended claims, the term “wires” refers to the components that lead from the respective bus to a comparator. Such wires are thin as they do not conduct static current.

Further, as used in the present specification and in the appended claims, the term “supply voltage” refers to either the supply voltage unaltered, or an altered representation of the supply voltage. For example, the supply voltage may pass first through a voltage reducer to reduce the value of what is supplied to the corresponding comparator.

Finally, as used in the present specification and in the appended claims, the term “a number of” or similar language is meant to be understood broadly as any positive number including 1 to infinity.

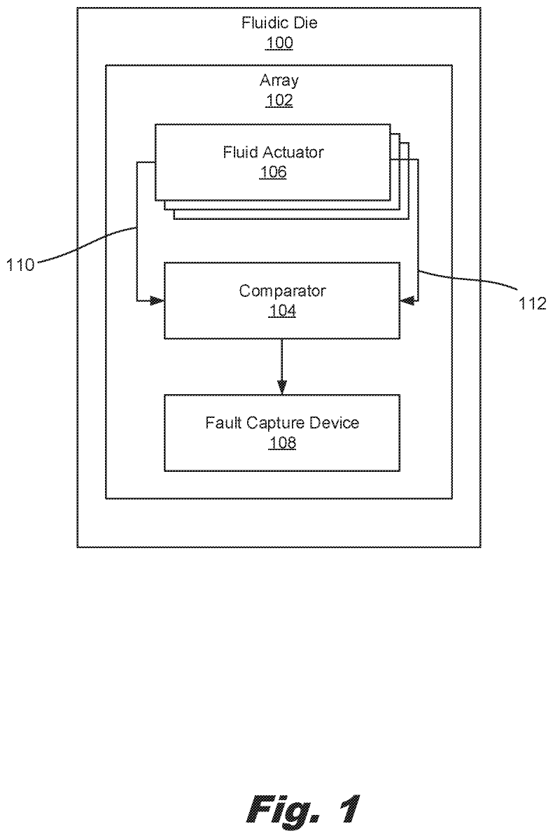

Turning now to the figures, FIG. 1 is a block diagram a fluidic die (100) for zonal actuator evaluation via wires (110, 112) along busses, according to an example of the principles described herein. As described above, the fluidic die (100) is a part of a fluidic system that houses components for ejecting fluid and/or transporting fluid along various pathways. In some examples, the fluidic die (100) is a microfluidic die (100). That is, the channels, slots, and reservoirs on the microfluidic die (100) may be on a micrometer, or smaller, scale to facilitate conveyance of small volumes of fluid (e.g., picoliter scale, nanoliter scale, microliter scale, milliliter scale, etc.). The fluid that is ejected and moved throughout the fluidic die (100) can be of various types including ink, biochemical agents, and/or fusing agents. The fluid is moved and/or ejected via an array (102) of fluid actuators (106), Any number of fluid actuators (106) may be formed on the fluidic die (100). The fluidic die (100) may include any number of arrays (102). For example, the different arrays (102) on a fluidic die (100) may be organized as columns, In other examples, the array (102) may take different forms such as an N×N grid of fluid actuators (106).

The fluidic die (100) includes a number of fluid chambers to hold a volume of the fluid to be moved or ejected. The fluid chamber may take many forms. A specific example of such a fluid chamber is an ejection chamber where fluid is held prior to ejection from the fluidic die (100). In another example, the fluid chamber (100) may be a channel, or conduit through which the fluid travels. In yet another example, the fluid chamber (100) may be a reservoir where a fluid is held.

The fluid chambers (100) formed in the fluidic die (100) include fluid actuators (106) disposed therein, which fluid actuators (106) work to eject fluid from, or move fluid throughout, the fluidic die (100). The fluid chambers and fluid actuators (106) may be of varying types. For example, the fluid chamber may be an ejection chamber wherein fluid is expelled from the fluidic die (100) onto a surface for example such as paper or a 3D build bed. In this example, the fluid actuator (106) may be an ejector that ejects fluid through an opening of the fluid chamber.

In another example, the fluid chamber is a channel through which fluid flows. That is, the fluidic die (100) may include an array of microfluidic channels. Each microfluidic channel includes a fluid actuator (106) that is a fluid pump. In this example, the fluid pump, when activated, displaces fluid within the microfluidic channel. While the present specification may make reference to particular types of fluid actuators (106), the fluidic die (100) may include any number and type of fluid actuators (106).

These fluid actuators (106) may rely on various mechanisms to eject/move fluid. For example, an ejector may be a firing resistor, The firing resistor heats up in response to an applied voltage. As the firing resistor heats up, a portion of the fluid in an ejection chamber vaporizes to generate a bubble. This bubble pushes fluid out an opening of the fluid chamber and onto a print medium, As the vaporized fluid bubble collapses, fluid is drawn into the ejection chamber from a passage that connects the fluid chamber to a fluid feed slot in the fluidic die (100), and the process repeats. In this example, the fluidic die (100) may be a thermal inkjet (TIJ) fluidic die (100).

In another example, the fluid actuator (106) may be a piezoelectric device. As a voltage is applied, the piezoelectric device changes shape which generates a pressure pulse in the fluid chamber that pushes the fluid through the chamber. In this example, the fluidic die (100) may be a piezoelectric inkjet (PIJ) fluidic die (100).

As described above, such fluid actuators (106) rely on energy to actuate. The energy seen by fluid actuators (106) is based on a voltage potential across the fluid actuator (106). Accordingly, the array (102) is coupled to a supply and a return. At various points along the array (102) the voltage on the supply side and the voltage seen on the return line may vary. For example, parasitic losses along the path of the supply line and return line may result in 1) decreases in the supply voltage seen at a particular location and/or 2) increases in the return voltage seen at a particular location. If 1) the supply voltage at a particular location is less than a predetermined threshold, 2) the return voltage at the particular location is greater than a predetermined threshold, or 3) combinations thereof, the voltage potential across the fluid actuators (106) at that location may be less than sufficient to facilitate fluid actuation. The fluid actuators (106) at that location may underperform, or may not perform at all. Accordingly, the fluidic die (100) includes fault detection device(s) that detect either kind of fault, i.e., a fault in the supply side or a fault in the return side. Such fault detection device(s) operate by comparing either a supply voltage or a return voltage against a respective threshold. In some examples, the supply voltage, return voltage, and/or respective thresholds may be scaled versions of such.

Such fault detection devices may be outside of an area defined by the fluid actuators (106). That is, the array (102) may include a column(s) of fluid actuators (106) and the fault detection device(s) may be outside of the column so as to de-populate an otherwise dense area of the fluidic die (100).

The fault detection device(s) includes many components. For example, the fluidic die (100) includes at least one comparator (104) that compares a representation of a supply voltage and/or a return voltage against a supply voltage threshold or return voltage threshold, respectively,

The return voltage value or supply voltage value that is compared against the respective threshold is affected by the position of supply wires (110) and return wires (112) along the supply busses and return busses of the fluidic die (100). That is, each array (102) may be coupled to a supply bus and a return bus which together generate a voltage differential across the fluid actuators (106) within the array (102). As described above, at different points along these busses, the parasitic losses may be different. Accordingly, at predetermined positions along these busses, supply wires (110) and return wires (112) may be coupled to take supply and return voltage measurements. That is, the supply wires (110) and return wires (112) respectively output a supply voltage level or return voltage level at the corresponding point along the respective supply bus or return bus. According to one example, the predetermined location coincides with a location where it is expected that the parasitic losses will be greatest, for example at a mid-point of a column array (102).

The comparator (104) receives as input, a voltage threshold, which threshold is a cutoff for sending an indication of a fault to a controller of the fluidic die (100). The comparator (104) may either 1) compare a supply voltage against a supply voltage threshold or 2) compare a return voltage against a return voltage threshold. For example, if the array (102) is supplied with a supply voltage of 32 V, the supply voltage threshold may be set at 28 V. In this example, the comparator (104) compares the supply voltage at a particular location, which may be less than 32 V, and compares it against the supply voltage threshold of 28 V. If the supply voltage drops below the threshold value, a fault-indicating output is passed to a controller. Similarly, if the supply voltage does not drop below the threshold value, a non-fault-indicating output is passed to the controller. Note that in this example, scaled versions of both the supply voltage at the particular location and a scaled version of the threshold may be used in such a comparison.

In another example, the comparator (104) receives as input, a return voltage threshold, which threshold is a cutoff for sending an indication of a return fault to a controller of the fluidic die (100). For example, if the array (102) is grounded to 0 V, the return voltage threshold may be set at 3 V. In this example, the comparator (104) compares the return voltage at a particular location, which may be greater than 0 V due to parasitic rise on the return bus, and compares it against the return voltage threshold of 3 V. If the return voltage rises above the threshold value, a fault-indicating output is passed to a controller. Similarly, if the return voltage does not rise above the threshold value, a non-fault-indicating output is passed to the controller.

In other words, the comparator (104) outputs a signal indicating either 1) a fault based on a fault-indicating output of the comparator (104) or 2) that the corresponding location is in a non-fault state. In this case, the fault-indicating output indicates either 1) that the supply voltage is less than the supply voltage threshold or 2) that the return voltage is greater than the return voltage threshold. As described above, the supply voltage may be the supply voltage, unaltered. In another example, the supply voltage may be scaled, or reduced.

Note that in this example, the comparator (104) can determine a fault based on either a supply voltage or a return voltage. Making such a determination based on just one side of the voltage differential is beneficial in that it reduces the circuitry on a fluidic die (100). Moreover, as the voltage differential between supply and threshold and return and threshold are mirrors, an overall drop in voltage differential based on the supply voltage and return voltage can be determined.

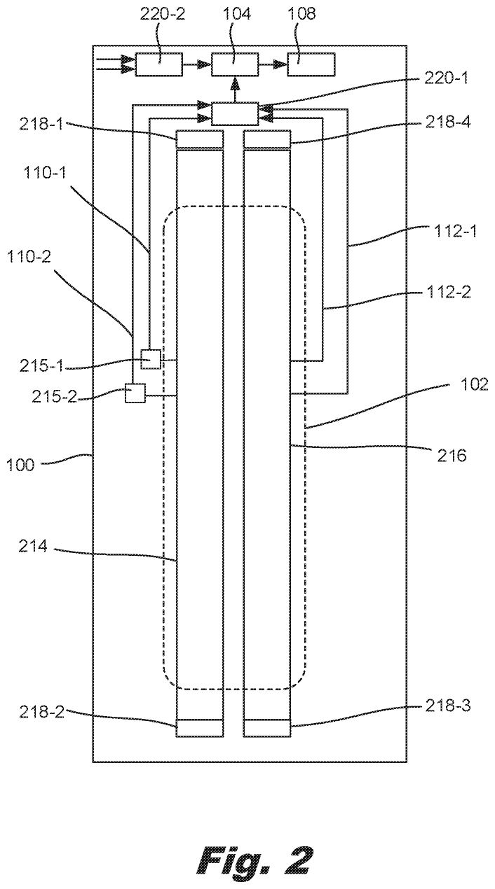

In another example, the comparator (104) compares both the supply voltage and the return voltage to a respective threshold. In one specific example, the fluidic die (100) includes a single comparator (104) to do so. In this example, each input of the comparator (104) is coupled to a multiplexer. A first multiplexer selectively couples a first input of the single comparator (104) to one of the supply wires (110) or one of the return wires (112) and a second multiplexer selectively couples a second input of the single comparator (104) to one of the supply voltage threshold and the return voltage threshold. One example of a single comparator (104) system is depicted in FIG. 2.

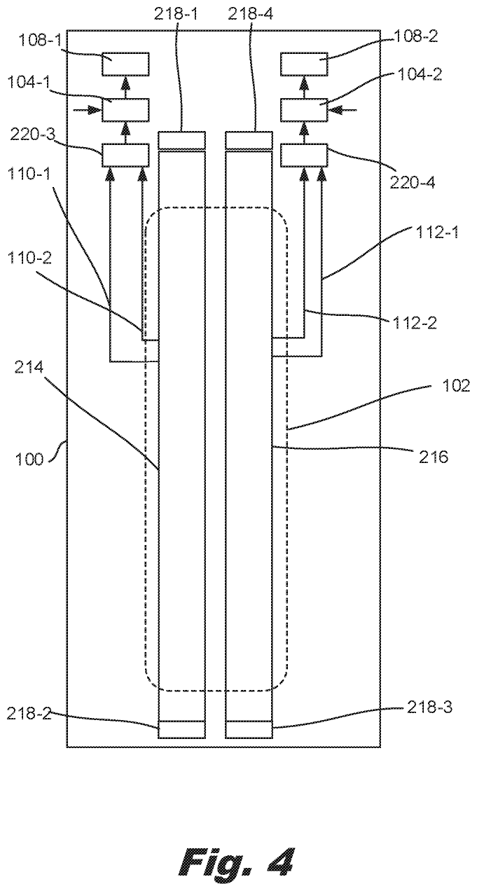

In another specific example of analyzing both the supply side and return side, the fluidic die (100) includes multiple comparators (104), In this example, one input of a first comparator (104) receives a value from a selected supply wire (110) and a second input of the first comparator (104) receives a supply voltage threshold. Further, one input of the second comparator (104) receives a value from a selected return wire (112) and a second input of the second comparator (104) receives the return voltage threshold. One example of a dual comparator (104) system is depicted in FIG. 4.

The fluidic die (100) also includes at least one fault capture device (108) to store an output of the comparator(s) (104). This output is then used by the fluidic die (100), or the system in which the fluidic die (100) is incorporated, to adjust parameters of the printing system to account for any detected fault. In the case of two comparators (104), the fluidic die (100) may include two fault capture devices (108). In the example of one comparator (104), the fluidic die (100) may include a single fault capture device (108).

Such a fluidic die (100) accounts for drops of power by providing an indication when power levels along the fluidic die (100) are insufficient to effectuate proper fluid actuation. For example, when, due to any number of circumstances, a particular location within the fluidic die (100) does not have sufficient voltage potential between its supply and return terminals to move and/or eject fluid as configured, a fault is triggered and an output passed to a controller of the fluidic die (100) such that a remedial action, such as adjusting print mask, power distribution, print speed, or firing parameters, can be carried out.

FIG. 2 is a diagram of a fluidic die (100) for zonal actuator evaluation via wires (110-1, 110-2, 112-1, 112-2) along busses (214, 216), according to an example of the principles described herein. As described above, a fluidic die (100) includes an array (102) of fluid actuators (FIG. 1, 106), which fluid actuators (FIG. 1, 106) operate to move and/or eject fluid throughout the fluidic die (100). FIG. 2 depicts the outline of the array (102) in dashed lines, In this example, the array (102) is a column array (102) where the individual actuators (FIG. 1, 106) are aligned as columns.

An energy potential is applied across the fluid actuators (FIG. 1, 106) in the array (102) by coupling the array (102) to a supply voltage, Vpp, and a return voltage, Vreturn. However, the voltages of Vpp and Vreturn at different points within the array (102) may be different due to different levels of parasitic loss along the path. The voltage differential between these two values Vpp and Vreturn at a particular location indicate whether or not the fluid actuators (106) at that location are receiving sufficient power to operate as expected. Accordingly, the fault detection devices is implemented to measure such a voltage difference and determine whether or not a fault, i.e., an insufficient voltage difference, exists.

Power is supplied to the fluid actuators (FIG. 1, 106) via busses (214, 216). Specifically, a supply bus (214) receives power from bond pads (218-1, 218-2) coupled to an off-die power supply and a return bus (216) returns electrical power from the bond pads (218-3, 218-4) to the power supply. As described above, such busses (214, 216) may be thin film conductive materials such as aluminum or gold. As a signal passes from the bond pads (218) to respective actuators (FIG. 1, 106), parasitic loss contributes to a reduced voltage potential across certain fluid actuators (FIG. 1, 106). This parasitic loss is most prevalent at those points farthest from the bond pads (218), i.e., the middle of the array (102). Accordingly, a fault detection system is implemented on the fluidic die (100) to detect such reduced voltage potentials. The fault detection system in the example depicted in FIG. 2 includes a single comparator (104) and a single fault capture device (108).

In this example, the one comparator (104) has a first input coupled to an output of a wire multiplexer (220-1) which selects one wire from among the supply wires (110-1, 110-2) and the return wires (112-1, 112-2). That is, the fluidic die (100) may include multiple supply wires (110-1, 110-2) and multiple return wires (112-1, 112-2) which are disposed at various points along their respective busses (214, 216). The location of where these wires (110, 112) attach to the respective busses (214, 216) may coincide with any predetermined location, such as those locations at which a power fault is likely to occur, such as a midpoint of the array (102). That is, the voltage on these wires (110, 112) outside the array (102) will be representative of the voltage on that point where the wire (110, 112) originates. In some examples, supply wires (110) and return wires (112) may be spaced along an entire length of the array (102) such that a power gradient can be determined. Accordingly, supply voltages and return voltages at different points along the respective busses (214, 216) can be determined and then used to determine whether a fault occurs. That is, if a supply voltage or a return voltage at a particular point is outside of the bounds defined by a threshold values, then it is likely a fault has occurred at that location, and a corresponding corrective action may be carried out.

Returning to the wire multiplexer (220-1), the wire multiplexer (220-1), via a control signal, selects one of the inputs, i.e., one of the supply wires (110-1, 110-2 or one of the return wires (112-1, 112-2). In some examples, voltage reducers (215-1, 215-2) may be disposed along the supply wires (110-1, 110-2) to generate the scaled versions of the supply voltages.

The coupled input is then passed to the single comparator (104). The single comparator (104) is also coupled to a threshold multiplexer (220-2) which selects between a supply voltage threshold and a return voltage threshold. That is, if a supply wire (110) is selected by the wire multiplexer (220-1) at a particular location, the supply voltage, Vpp, on that supply wire (110) and a supply voltage threshold, Vpp threshold, are passed to the comparator (104). The comparator (104) compares these two voltages and generates an output that is passed to a fault capture device (108). Note that if the supply voltage has been scaled, the supply voltage threshold, Vpp threshold, is scaled to a similar degree. The fault capture device (108) is a component that receives the output of the comparator (104).

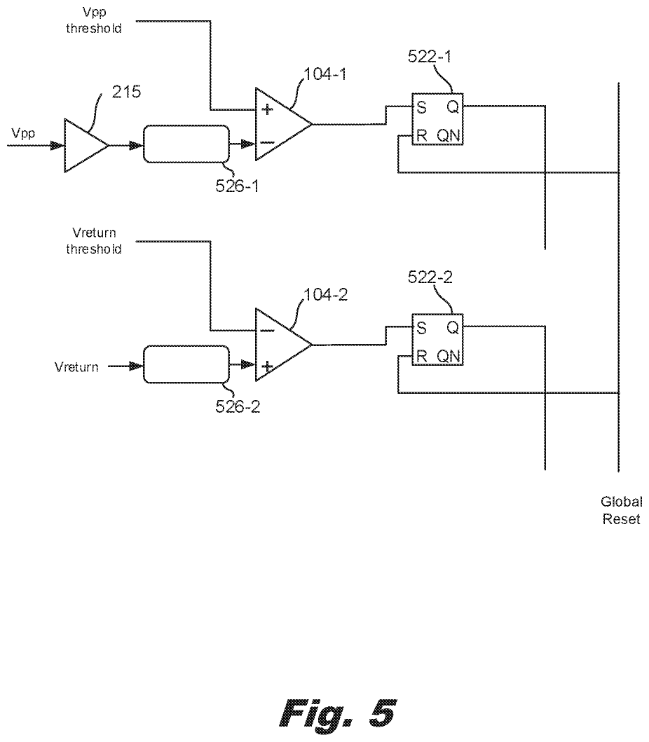

By comparison, if a return wire (112) is selected by the wire multiplexer (220-1) at a particular location, the return voltage, Vreturn, on that return wire (112) and a return voltage threshold, Vreturn threshold, are passed to the comparator (104) where a comparison is made and an output stored on the capture device (108). The fault capture device (108) may then, at a predetermined point in time, pass the output to a controller such that operation of the fluidic die (100) can be adjusted. More detail regarding the operation of the comparator (104) and the fluid capture device (108) are provided below in connection with FIG. 5. Note that in this example, there is little to no electrical load on the supply wires (110) or the return wires (112) such that parasitic drop/rise over the supply wires (110) and the return wires (112) is minimized.

Note that as depicted in FIG. 2, in some examples, the at least one comparator (104) and at least one fault capture device (108) are outside of the area defined by the array (102) of fluid actuators (FIG. 1, 106). Also, in this particular example, the various multiplexers (220) are outside of this same area, which is indicated by the dashed line. That is, the array (102) may be a column(s) of fluid actuators (FIG. 1, 106). In this example, the fault detection circuitry, i.e., the multiplexers (220), comparator(s) (104), and fault capture device(s) (108) are disposed outside of this column. Doing so decongests the area of the fluidic die (100) that is most densely occupied, i.e., where the fluid actuators (FIG. 1, 106) are. Doing so may reduce the complexity of a fluidic die (100) which may increase fluidic die (100) operational life and efficacy.

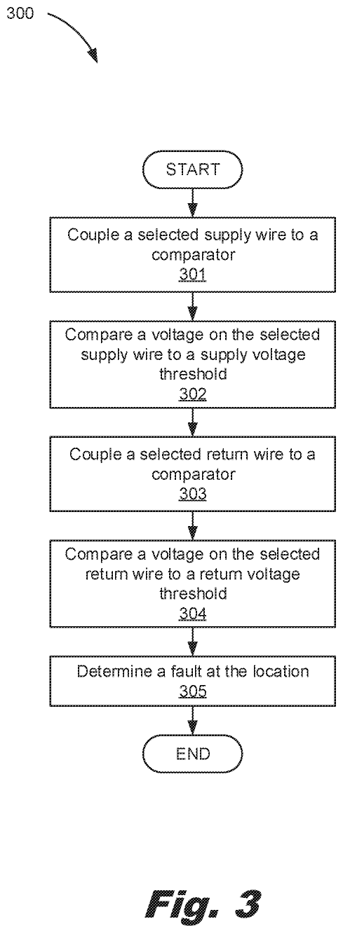

FIG. 3 is a flow chart of a method (300) for zonal actuator evaluation via wires (FIG. 1, 110, 112) along busses (FIG. 2, 214, 216), according to an example of the principles described herein. According to the method (300), a selected supply wire (FIG. 1, 110) of multiple supply wires (FIG. 1, 110) is coupled (block 301) to a comparator (FIG. 1, 104). As described above, the supply wires (FIG. 1, 110) 1) are coupled to a supply bus (FIG. 2, 214) at locations where it is desired to know a power supplied to fluid actuators (FIGS. 1, 106) and 2) output a supply voltage at that location. Such a location may be a location where it is likely a power fault may occur, such as at a midpoint of a column array (FIG. 1, 102).

Also, as described above, in some examples a single comparator (FIG. 1, 104) may be used, and in other examples multiple comparators (FIG. 1, 104) may be used. In the example of a single comparator (FIG. 1, 104), this single comparator (FIG. 1, 104) may be multiplexed to a single one of the supply wires (FIG. 1, 110) and return wires (FIG. 1, 112). Accordingly, coupling (block 301) a supply wire (FIG. 1, 110) to the comparator (FIG. 1, 104) includes activating an input of a wire multiplexer (FIG. 2, 220-1) corresponding to the selected supply wire (FIG. 1, 110) to the comparator (FIG. 1, 104).

In the example where multiple comparators (FIG. 1, 104) are used, a first comparator (FIG. 1, 104) may be used to compare supply voltages at different locations to supply voltage thresholds. Accordingly, coupling (block 301) a supply wire (FIG. 1, 110) to the comparator (FIG. 1, 104) includes activating an input of a supply multiplexer (FIG. 2, 220), which supply multiplexer (FIG. 2, 220) is coupled just to supply wires (FIG. 1, 110), to the selected supply wire (FIG. 1, 110) to the comparator (FIG. 1, 104).

With the appropriate supply wire (FIG. 1, 110) coupled (block 301) to an appropriate comparator (FIG. 1, 104), the voltage on the supply wire (FIG. 1, 110) is compared (block 302) to a supply voltage threshold. In the case of a single comparator (FIG. 1, 104), this supply voltage threshold may be provided via a threshold multiplexer (FIG. 2, 220-2) to the single comparator (FIG. 1, 104). In the case of a supply-specific comparator (FIG. 1, 104), this supply voltage threshold may be directly tied to an input of the comparator (FIG. 1, 104).

That is, a representation of a supply voltage, Vpp, at a particular location is compared (block 302) against a supply voltage threshold, Vpp threshold. The supply voltage threshold, Vpp threshold, may be any value less than the supply voltage, Vpp, where it is deemed that sub-threshold voltages would result in less than a desired level of performance by the fluid actuators (FIG. 1, 106). Note also that the supply voltages, Vpp, may differ at different locations along the array (FIG. 1, 102). Accordingly, by comparing the supply voltage threshold, Vpp threshold, with the specific supply voltage, Vpp, seen at location, a localized result based on the actual operation of a particular fluid system can be determined.

According to the method (300), a selected return wire (FIG. 1, 112) of multiple return wires (FIG. 1, 112) is coupled (block 303) to a comparator (FIG. 1, 104). As described above the return wires (FIG. 1, 112) 1) are coupled to a return bus (FIG. 2, 216) at locations where it is desired to know a power supplied to fluid actuators (FIGS. 1, 106) and 2) output a return voltage at that location.

Such a location may be a location where it is likely a power fault may occur, such as at a midpoint of a column array (FIG. 1, 102).

Also, as described above, in some examples a single comparator (FIG. 1, 104) may be used, and in other examples multiple comparators (FIG. 1, 104) may be used. In the example of a single comparator (FIG. 1, 104), this single comparator (FIG. 1, 104) may be multiplexed to a single one of the supply wires (FIG. 1, 110) and return wires (FIG. 1, 112). Accordingly, coupling (block 303) a selected return wire (FIG. 1, 112) to the comparator (FIG. 1, 104) includes activating an input of a wire multiplexer (FIG. 2, 220-1) corresponding to the selected return wire (FIG. 1, 112) to the comparator (FIG. 1, 104).

In the example, where multiple comparators (FIG. 1, 104) are used, a second comparator (FIG. 1, 104) may be used to compare return voltages at different locations to return voltage thresholds. Accordingly, coupling (block 303) a return wire (FIG. 1, 110) to the comparator (FIG. 1, 104) includes activating an input of a return multiplexer (FIG. 2, 220), which return multiplexer (FIG. 2, 220) is coupled just to return wires (FIG. 1, 112), to the selected return wire (FIG. 1, 110) to the comparator (FIG. 1, 104).

With the appropriate return wire (FIG. 1, 112) coupled (block 303) to an appropriate comparator (FIG. 1, 104), the voltage on the return wire (FIG. 1, 112) is compared (block 304) to a return voltage threshold. In the case of a single comparator (FIG. 1, 104), this return voltage threshold may be provided via a threshold multiplexer (FIG. 2, 220-2) to the single comparator (FIG. 1, 104). In the case of a return-specific comparator (FIG. 1, 104), this return voltage threshold may be directly tied to the comparator (FIG. 1, 104).

That is, a representation of a return voltage, Vreturn, at a particular location is compared (block 304) against a return voltage threshold, Vreturn threshold. The return voltage threshold, Vreturn threshold, may be any value less than the return voltage, Vreturn, where it is deemed that supra-threshold voltages would result in less than a desired level of performance by the fluid actuators (FIG. 1, 106). Note also that the return voltages, Vreturn, may differ at different locations along the array (FIG. 1, 102). Accordingly, by comparing the return voltage threshold, Vreturn threshold, with the specific return voltage, Vreturn, seen at location, a localized result based on the actual operation of a particular fluid system can be determined.

Note that while FIG. 3 depicts the comparisons occurring in a particular order, i.e., a supply comparison prior to a return comparison, the comparisons may occur in any order.

With these comparisons (block 302, 304) made, the system can determine (block 305) a fault at the location. Specifically, a fault is determined (block 305) when either 1) the supply voltage, Vpp, at the location is less than the supply voltage threshold, Vpp threshold or 2) the return voltage, Vreturn, at the location is greater than the return voltage threshold, Vreturn threshold. For example, given a supply voltage threshold of 28 V and a return voltage threshold of 3 V, a fault may be determined when the supply voltage, Vpp, at the location falls below 28 V or the return voltage, Vreturn, at the location is greater than 3 V. When either of these cases exists, it is indicative that a voltage potential across the actuators (FIG. 1, 106) at that location is insufficient to allow fluid actuator (FIG. 1, 106) operation as intended. Again as noted above, while reference is made to a 28 V threshold, the supply voltage and supply voltage threshold may both be scaled to support low voltage circuitry.

FIG. 4 is a diagram of a fluidic die (100) for zonal actuator evaluation via wires (110-1, 110-2, 112-1, 112-2) along busses (214, 216), according to an example of the principles described herein. As described above, in some examples, the at least one comparator (104) includes two comparators (104-1, 104-2). Such an example is depicted in FIG. 4. In this example, the first comparator (104-1) compares voltages of at least one supply wire (110) of the set of supply wires (110) to a supply voltage threshold. As there may be multiple supply wires (110), a particular supply wire (110) to be compared against the supply voltage threshold is determined via a supply multiplexer (220-3). In this example, the output of the supply multiplexer (220-3) and a supply voltage threshold are passed to a first comparator (104-1) which makes a comparison to determine whether a supply side fault exists. This output is then passed to a first fault capture device (108-1) where it can be subsequently passed to a controller for print operation adjustment. Note that in the example depicted in FIG. 4, no voltage reducer is disposed along the supply wires (110).

The second comparator (104-2) compares voltages of at least one return wire (110-1) of the set of return wires (110). As there may be multiple return wires (112), a particular return wire (112) to be compared against a return voltage threshold is determined via a return multiplexer (220-4). In this example, the output of the return multiplexer (220-4) and a return voltage threshold are passed to a second comparator (104-2) which makes a comparison to determine whether a return side fault exists. This output is then passed to a second fault capture device (108-2) where it can be subsequently passed to a controller for print operation adjustment.

Note that as depicted in FIG. 4, in some examples, the comparators (104-1, 104-2), fault capture devices (108-1, 108-2), and multiplexers (220-3, 220-4) are outside of the area defined by the array (102) of fluid actuators (FIG. 1, 106). Doing so decongests the area of the fluidic die (100) that is most densely occupied, i.e., where the fluid actuators (FIG. 1, 106) are. Doing so may reduce the complexity and cost of a fluidic die (100) which may increase fluidic die (100) operational life and efficacy.

FIG. 5 is a circuit diagram of comparators (104) and fault capture devices (FIG. 1, 108), according to an example of the principles described herein. As described above, each fluidic die (FIG. 1, 100) includes at least one comparator (104) and in some examples two or more comparators (104-1, 104-2). FIG. 5 depicts an example with two comparators (104-1, 104-2). In the example depicted in FIG. 5, a first comparator (104-1) is comparing a supply voltage, Vpp, against a supply voltage threshold, Vpp threshold and a second comparator (104-2) is comparing a return voltage, Vreturn, against a return voltage threshold, Vreturn threshold, Any of the input values to the comparators (104) may originate from multiplexers as described above.

Also as described above, the fluidic die (100) includes at least one fault capture device (FIG. 1, 108). In the example depicted in FIG. 5, two fault capture devices (FIG. 1, 108) are depicted, the fault capture devices (FIG. 1, 108) being S-R flops (522-1, 522-2), however other types of flops such as D-flops may be used.

An example of the operation of this example is now provided. Prior to any fault detection, the R terminal of the first S-R flop (522-1) is driven by the global reset line to an active state so that all Q terminals drive to 0.

In this example, the first comparator (104-1) has its “+” terminal connected to the supply threshold voltage, Vpp threshold. In some examples such a connection may be indirect. That is, the supply threshold voltage, Vpp threshold, may pass through a sample and hold device, which sample and hold device includes a capacitor to store the supply voltage threshold, Vpp threshold, until evaluation and a transistor to allow the supply voltage threshold, Vpp threshold, to pass to the capacitor during a predetermined period such as during a quiescent period.

The “−” terminal of the first comparator (104-1) is connected to the representation of the supply voltage, Vpp. Note that in some examples, the supply voltage first passes through a low pass filter (526) and/or a voltage reducer. In the example depicted in FIG. 5, the low pass filters (526-1, 526-2) are disposed on an input of a respective comparator (104) on which the supply voltage or return voltage is received. However, in some examples the low pass filters (526) may be disposed on an output of the comparators (104). In other examples, the comparators (104-1, 104-2) themselves perform a filtering function. The low pass filters (526) filters out noise that may be found along the path of the supply and return voltages. Such noise may cause false triggers. Accordingly, the low pass filters (526) prevent such false fault triggers.

During operation, the first comparator (104-1) maintains a “0” logic, indicating expected operation, i.e., that the supply voltage, Vpp, at the location is greater than or equal to the supply voltage threshold, Vpp threshold. In the event that the supply voltage, Vpp, falls below the threshold, Vpp threshold, the output of the first comparator (104-1) will transition from a “0” to a “1” causing the first S-R flop (522-1) to be set to a “1” and output that “1” along the “Q” terminal to be passed to a controller. This “1” indicating a supply fault will be communicated to the global die logic, and possibly to the printer. This “1” will remain on the first S-R flop (522-1) until the first S-R flop (522-1) is reset. That is, a reset device, in this example the “R” terminal and the global reset line, resets the respective fault capture device (FIG. 1, 108), in this example, the S-R flop (522) after the fault has been acknowledged by a controller.

Similar to the first S-R flop (522-1), prior to any fault detection, the R terminal of the second S-R flop (522-2) is driven by the global reset line to an active state so that all Q terminals drive to 0.

In this example, the second comparator (104-2) has its “−” terminal connected to the return threshold voltage, Vreturn threshold. In some examples such a connection may be indirect. That is, the return threshold voltage, Vreturn threshold, may pass through a sample and hold device which sample and hold device includes a capacitor to store the return voltage threshold, Vreturn threshold, until evaluation and a transistor to allow the return voltage threshold, Vreturn threshold, to pass to the capacitor during a predetermined period such as during a quiescent period. The “+” terminal of the second comparator (104-2) is connected to the return voltage, Vreturn. Note that in some examples, the return voltage first passes through a low pass filter (526-2).

During operation, the second comparator (104-2) maintains a “0” logic, indicating expected operation, i.e., that the return voltage, Vreturn, at the location is less than or equal to the return voltage threshold, Vreturn threshold. In the event that the return voltage, Vreturn, rises above the threshold, Vreturn threshold, the output of the second comparator (104-2) will transition from a “0” to a “1” causing the second S-R flop (522-2) to be set to a “1” and output that “1” along the “Q” terminal to be passed to a controller. This “1” indicating a return fault will be communicated to the global die logic, and possibly to the printer. This “1” will remain on the second S-R flop (522-2) until the second S-R flop (522-2) is reset. That is, a reset device, in this example the “R” terminal and the global reset line, resets the respective fault capture device (FIG. 1, 108), in this example, the S-R flop (522) after the fault has been acknowledged by a controller.

As described above, in some examples, a voltage reducer (215) is disposed along the supply wires (FIG. 1, 110) to reduce high voltage supply voltages to operate with low voltage circuitry. The voltage reducer (215) may scale a high voltage to a low voltage. Using such voltage reducers (215) further reduce the cost and complexity as low voltage circuitry is less complex and less costly than circuitry that would be used to accommodate high voltage values.

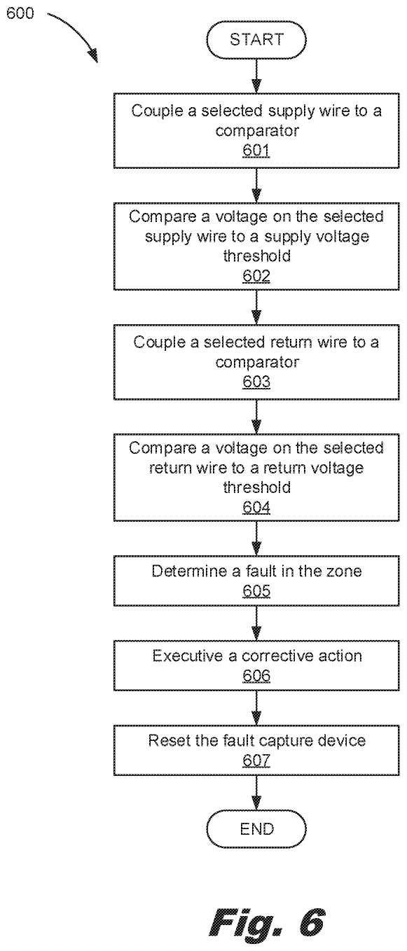

FIG. 6 is a flow chart of a method (600) for zonal actuator evaluation via wires (FIG. 1, 110, 112) along busses (FIG. 2, 214, 216), according to an example of the principles described herein. According to the method (600), a selected supply wire (FIG. 1, 110) is coupled (block 601) to a comparator (FIG. 1, 104) and a voltage on the selected supply wire (FIG. 1, 110) is compared (block 602) against a supply voltage threshold. This may be performed as described above in connection with FIG. 3.

According to the method (600), a selected return wire (FIG. 1, 112) is coupled (block 603) to a comparator (FIG. 1, 104) and a voltage on the selected return wire (FIG. 1, 112) is compared (block 604) against a return voltage threshold. This may be performed as described above in connection with FIG. 3.

With these comparisons (block 602, 604), a determination (block 605) is made regarding a fault at the location. This may be performed as described above in connection with FIG. 3. Specifically, a fault is determined (block 605) when, at a particular location, either 1) the supply voltage, Vpp, is less than the supply voltage threshold, Vpp threshold or 2) the return voltage, Vreturn, is greater than the return voltage threshold, Vreturn threshold.

For example, given a supply voltage threshold of 28 V and a return voltage threshold of 3 V, a fault may be determined when the supply voltage, Vpp, at a location falls below 28 V or the return voltage, Vreturn is greater than 3 V. When either of these cases exists, it is indicative that a voltage potential at that location is insufficient to allow fluid actuator (FIG. 1, 106) operation as intended.

A signal indicative of a fault is then propagated to a controller. Accordingly, the method (600) as described herein describes detection of a fault on the fluidic die (FIG. 1, 100) based on the specific operating parameters, i.e., Vpp and Vreturn, for that particular location.

Corrective actions may then be executed (block 608) based on an indication of the fault. For example, print masks may be adjusted, power settings, print speeds, or firing parameters may be adjusted, and other parameters may be adjusted. In one example, the corrective action includes providing a notification to a printer or a user such that manual corrective actions such as maintenance or replacement may occur. Following such corrective action, the fault capture devices (FIG. 2, 212) may be reset (block 607) to no longer indicate a fault.

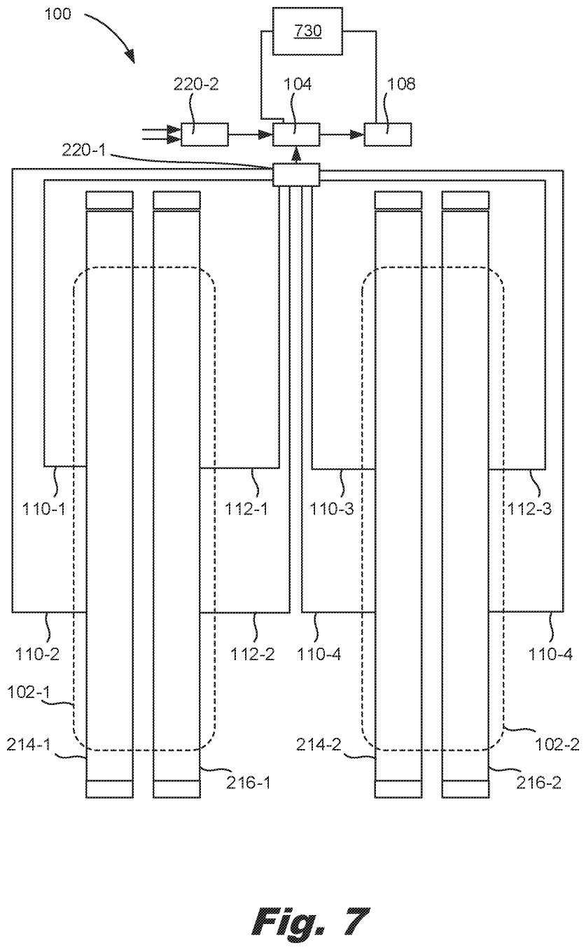

FIG. 7 is a diagram of a fluidic die (100) for zonal actuator evaluation via wires (110, 112) along busses (214, 216), according to an example of the principles described herein. As described above, the fluidic die (100) may include any number of arrays (102). In some examples, those arrays (102-1, 102-2) may share the comparator (104) and other associated circuitry such as the multiplexers (220) and the fault capture devices (108). That is, multiple arrays (102-1, 102-2) may use the at least one comparator (104). Moreover, while FIG. 7 depicts supply bond pads and return bond pads unique to each array (102). In some examples, the supply busses (214-1, 214-2) of the multiple arrays (102-1, 102-2) may be coupled to a shared bond pad. Similarly, the return busses (216-1, 216-2) of the multiple arrays (102-1, 102-2) may be coupled to a shared bond pad.

FIG. 7 also depicts a controller (730) that may be off die or on die and that enables at least one of the comparator (104) and the fault capture device (108). For example, in some cases it may be desirable to perform actuator evaluation during a predetermined time, for example when the transmission lines that receive the threshold voltages are less susceptible to noise. In another example, the predetermined time may be a time when a maximum possible number of actuators are simultaneously firing. Doing so is a “worst case” scenario and thereby represents the period of time most likely to experience a power fault. Accordingly, the controller (730) may enable at least one of the comparator (104) and the fault capture device (108) during these periods of time.

Any of the evaluation components, i.e., the multiplexers (220), comparator (104), and/or fault capture device (108) may carry out other operations on the fluidic die (100). For example, such comparators and output devices may be tied to a thermal measurement system of the fluidic die (100) and may be used in those systems. Accordingly, in these examples the thermal measurement inputs would be multiplexed with the power fault detection inputs.

Note that as depicted in FIG. 7, in some examples, the comparator (104), fault capture device (108), and multiplexers (220-1, 220-2) are outside of the area defined by the array (102) of fluid actuators (FIG. 1, 106). Doing so decongests the area of the fluidic die (100) that is most densely occupied, i.e., where the fluid actuators (FIG. 1, 106) are. Doing so may reduce the complexity of a fluidic die (100) which may increase fluidic die (100) operational life and efficacy.

In one example, using such a fluidic die 1) allows for immediate detection of power faults at particular locations within the array of fluid actuators; 2) reports such faults such that remedial action may be taken; 3) allows for a controller to adjust print masks, power distribution, or other parameters, on the fly to optimize for the actual power delivery limitations of the system; 4) can repurpose existing fluidic die elements; 5) implements supply and return wires having a small width; and 6) removes detection circuitry from within an actuator array.

What is claimed is:

1. A fluidic die, comprising:
an array of fluid actuators;
a number of wires disposed at various points along at least one of a supply bus and a return bus that are coupled to the actuators in the array, the wires to output a voltage level at a corresponding point of the respective bus;
at least one comparator to compare a voltage of a selected wire against a voltage threshold; and
at least one fault capture device to output a signal indicating a fault based on the output of the at least one comparator.

2. The fluidic die of claim 1, wherein the at least one comparator and the at least one fault capture device are outside of an area defined by the array of fluid actuators.

3. The fluidic die of claim 1, wherein the at least one comparator is used by multiple arrays on the fluidic die.

4. The fluidic die of claim 1, further comprising a controller to enable, via an enable signal, at least one of:
the at least one comparator; and
the at least one fault capture device.

5. The fluidic die of claim 1, wherein:
the number of wires comprises:
a number of supply wires disposed at various points along a supply bus, the supply wires to output a supply voltage level at a corresponding point of the supply bus;
a number of return wires disposed at various points along a return bus, the return wires to output a return voltage level at a corresponding point of the return respective bus; and
the at least one comparator is to:
compare a voltage of a selected supply wire against a supply voltage threshold; and
compare a voltage of a selected return wire against a return voltage threshold.

6. The fluidic die of claim 5, wherein:
the at least one comparator comprises one comparator;
a first input of the at least one comparator is coupled to an output of a multiplexer which selects a particular supply wire or a particular return wire; and
a second input of the at least one comparator coupled to an output of a multiplexer which selects between the supply voltage threshold and the return voltage threshold.

7. The fluidic die of claim 5, wherein:
at least one of the supply wires is disposed at a midpoint of the array; and
at least one of the return wires is disposed at the midpoint of the array.

8. The fluidic die of claim 5, further comprising a number of buffers, a buffer being disposed on each supply wire and each return wire.

9. The fluidic die of claim 5, wherein:
the number of supply wires comprises multiple supply wires;
the number of return wires comprises multiple return wires; and
the fluidic die further comprises a multiplexer to couple one of the multiple supply wires or one of the multiple return wires to the at least one comparator.

10. The fluidic die of claim 5, wherein:
the at least one comparator comprises two comparators;
a first comparator to compare the voltage of the selected supply wire against the supply voltage threshold; and
a second comparator to compare the voltage of the selected return wire against the return voltage threshold.

11. The fluidic die of claim 10, wherein:
the number of supply wires comprises multiple supply wires;
the fluidic die further comprises a first multiplexer to couple one of the multiple supply wires to the first comparator;
the number of return wires comprises multiple return wires; and
the die further comprises a second multiplexer to couple one of the multiple return wires to the second comparator.

12. A method comprising:
coupling a selected supply wire, of multiple supply wires, to a comparator, wherein the supply wires:
are disposed at various points along a supply bus that is coupled to fluid actuators in an array; and
are to output a supply voltage level at a corresponding point of the supply bus;
comparing a voltage on the selected supply wire against a supply voltage threshold;
coupling a selected return wire, of multiple return wires, to a comparator, wherein the return wires:
are disposed at various points along a return bus that is coupled to the fluid actuators in the array; and
are to output a return voltage level at a corresponding point of the return bus;
comparing a voltage on the selected return wire against a return voltage threshold; and
determining a fault at the location when at least one of the following conditions exists;
the voltage on the supply wire is less than the supply voltage threshold; and
the voltage on the return wire is greater than the return voltage threshold.

13. The method of claim 12, further comprising executing a corrective action based on an indication of the fault.

14. A fluidic die, comprising:
an array of fluid actuators;
multiple supply wires disposed at various points along a supply bus that is coupled to the array_{;} the supply wires to output a voltage level at a corresponding point of the supply bus;
multiple return wires disposed at various points along a return bus that is coupled to the array, the return wires to output a voltage level at a corresponding point of the return bus;
a first multiplexer to couple a selected supply wire to a first comparator;
the first comparator to compare a voltage of the selected supply wire against a supply voltage threshold;
a first fault capture device to output a signal indicating a fault based on the output of the first comparator;
a second multiplexer to couple a selected return wire to a second comparator;
the second comparator to compare a voltage of the selected return wire against a return voltage threshold; and
a second fault capture device to output a signal indicating a fault based on the output of the second comparator,
wherein the comparators, multiplexers, and fault capture devices are outside of an area defined by the array.

15. The fluidic die of claim 14, further comprising a number of low pass filters, wherein a low pass filter is disposed on at least one of:
an input of a comparator; and
an output of a comparator.
